(19) United States
(12) Patent Application Publication
(10) Pub. No.: US 2018/0119302 A1
(43) Pub. Date: May 3, 2018

(54) ELECTROPLATING APPARATUS AND ELECTROPLATING METHOD

(71) Applicant: Samsung Electronics Co., Ltd., Suwon-si (KR)

(72) Inventors: Dong-Chan LIM, Suwon-si (KR); Kwang-Jin MOON, Hwaseong-si (KR); Byung-Lyul PARK, Seoul (KR); Nae-In LEE, Seoul (KR); Ho-Jin LEE, Seoul (KR)

(21) Appl. No.: 15/797,472

(22) Filed: Oct. 30, 2017

(30) Foreign Application Priority Data
Nov. 1, 2016 (KR) 10-2016-0144763

(51) Int. Cl. C25D 5/00; C25D 7/12; C25D 17/00; C25D 21/12; H01L 21/288; H01L 21/768

(52) U.S. Cl. CPC C25D 5/006; C25D 7/123; H01L 21/76873; C25D 21/12; H01L 21/2885; C25D 17/001

(57) ABSTRACT

An electroplating apparatus includes an electroplating bath including an anode installed therein and a plating solution received therein, a substrate holder configured to hold a substrate to be submerged into the plating solution and including a support surrounding the substrate and a cathode on the support to be electrically connected to a periphery of the substrate, a magnetic field generating assembly provided in the support and including at least one electromagnetic coil extending along a circumference of the substrate, and a power supply configured to current to the electromagnetic coil.

### PRIORITY STATEMENT

This application claims priority under 35 U.S.C. § 119 to Korean Patent Application No. 10-2016-0144763, filed on Nov. 1, 2016 in the Korean Intellectual Property Office (KIPO), the contents of which are herein incorporated by reference in its entirety.

### BACKGROUND

Example embodiments of the inventive concepts relate to an electroplating apparatus and an electroplating method. More particularly, example embodiments of the inventive concepts relate to an electroplating apparatus for plating a metal layer on a surface of a wafer and an electroplating method using the same.

In semiconductor manufacturing processes such as Cu damascene process, TSV process, etc., an electroplating apparatus may be used to form a metal layer on a substrate such as a wafer. In particular, after a seed layer is formed on a surface of the substrate, current may be applied to the seed layer to deposit metal ions (for example, copper ion (Cu²⁺)) in a plating solution to form the metal layer. However, because current flows through the seed layer having a relatively small thickness, thickness uniformity of the plated layer may be deteriorated due to a resistance difference between a peripheral region and the middle region of the substrate.

### SUMMARY

Example embodiments of the inventive concepts provide an electroplating apparatus capable of depositing a uniform, or more uniform, metal layer.

Example embodiments of the inventive concepts provide an electroplating method of depositing a uniform, or more uniform, metal layer using the electroplating apparatus.

According to example embodiments of the inventive concepts, an electroplating apparatus includes an electroplating bath including an anode installed therein and a plating solution received therein, a substrate holder configured to hold a substrate to be submerged into the plating solution and including a support surrounding the substrate and a cathode on the support to be electrically connected to a periphery of the substrate, a magnetic field generating assembly provided in the support and including at least one electromagnetic coil extending along a circumference of the substrate, and a power supply configured to current to the electromagnetic coil.

According to example embodiments of the inventive concepts, an electroplating apparatus includes an electroplating bath including a plating solution received therein, a substrate holder configured to hold a substrate to be submerged into the plating solution, an anode within the electroplating bath, a cathode electrically contacting a periphery of the substrate, a magnetic field generating assembly on the electroplating bath and including at least one electromagnetic coil extending along a circumference of the substrate, and a power supply configured to current to the electromagnetic coil.

According to example embodiments of the inventive concepts, in an electroplating method, a plating solution including metal ions is provided to an electroplating bath. A substrate is held by a substrate holder on the electroplating bath such that a surface of the substrate is submerged into the plating solution. Current is applied through the substrate to deposit a metal layer on the surface of the substrate. Current is applied to at least one electromagnetic coil extending along a circumference of the substrate to form an electromagnetic force on the metal layers to be deposited on the substrate.

According to example embodiments of the inventive concepts, an electroplating apparatus may include a magnetic field generating assembly having at least one electromagnetic coil extending in a circumferential direction along a circumference of a wafer. As current flows through the electromagnetic coil, a magnetic field may be generated on a peripheral region of the wafer. Thus, a magnetic force may be exerted on metal ions moving toward the peripheral region of the wafer such that some of the metal ions deviate from the peripheral region of the wafer and move outwardly in an outer radial direction.

According to example embodiments of the inventive concepts, an electroplating apparatus may include a first electromagnetic coil configured to extend along a perimeter of a substrate, a first power supply configured to provide a first current through the substrate to electrochemically deposit metal ions to form a metal layer on the substrate, and a second power supply configured to supply a second current to the first electromagnetic coil to form an electromagnetic force acting on the metal ions to move outwardly from a periphery of the substrate

Accordingly, the number of the metal ions deposited on the peripheral region of the wafer may be reduced, to thereby decrease a thickness of the metal layer deposited on the peripheral region of the wafer. Thus, the metal layer having a uniform, or more uniform, thickness across the entire surface of the wafer may be formed.

### BRIEF DESCRIPTION OF THE DRAWINGS

Example embodiments of the inventive concepts will be more clearly understood from the following detailed description taken in conjunction with the accompanying drawings. FIGS. 1 to 13 represent non-limiting, example embodiments of the inventive concepts as described herein.

FIG. 1 is a cross-sectional view illustrating an electroplating apparatus in accordance with example embodiments of the inventive concepts.

FIG. 2 is a cross-sectional view illustrating a portion of a substrate holder of the electroplating apparatus in FIG. 1.

FIG. 3 is a plan view illustrating a magnetic field generating assembly of the electroplating apparatus in FIG. 1.

FIG. 4 is a perspective view illustrating portions of electromagnetic coils of the magnetic field generating assembly in FIG. 3.

FIGS. 5A and 5B are cross-sectional views illustrating magnetic fields generated by the electromagnetic coils of the magnetic field generating assembly.

FIG. 6 is a circuit diagram illustrating a current difference between a center and a periphery of a wafer dipped into a plating solution in an electroplating bath in FIG. 1.

FIG. 7 is a cross-sectional view illustrating an electroplating apparatus in accordance with example embodiments of the inventive concepts.

FIG. 8 is a plan view illustrating first and second magnetic field generating assemblies of the electroplating apparatus in FIG. 7.

FIG. 9 is a flow chart illustrating an electroplating method in accordance with example embodiments of the inventive concepts.

FIGS. 10 to 13 are views illustrating a method of manufacturing a semiconductor device package in accordance with example embodiments of the inventive concepts.

### DETAILED DESCRIPTION

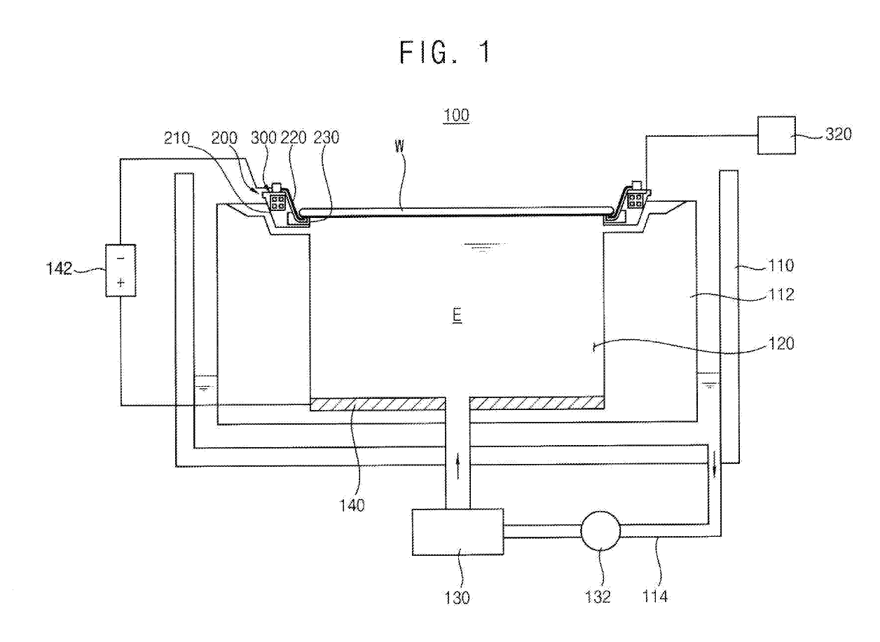

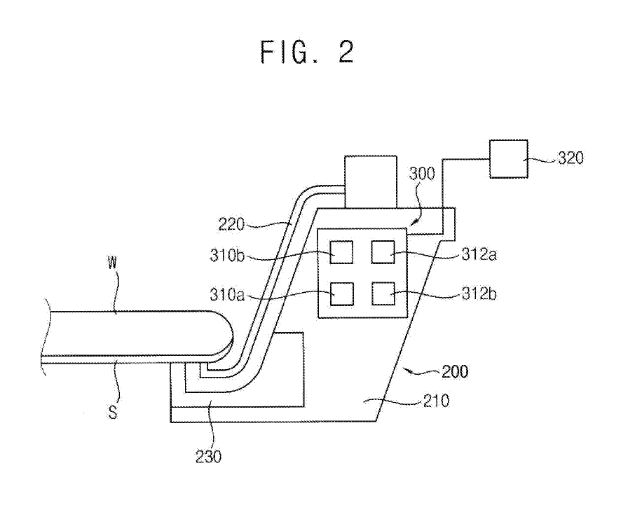

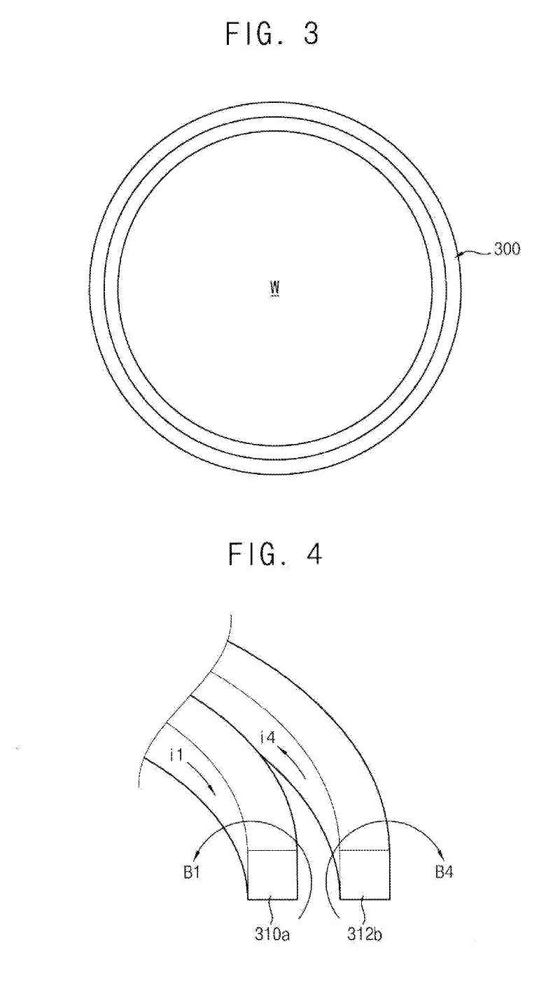

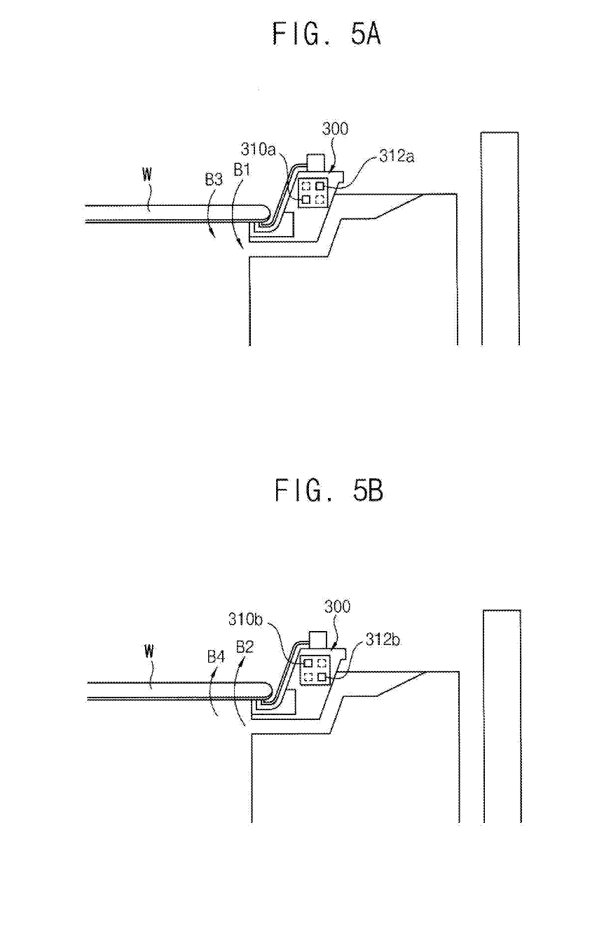

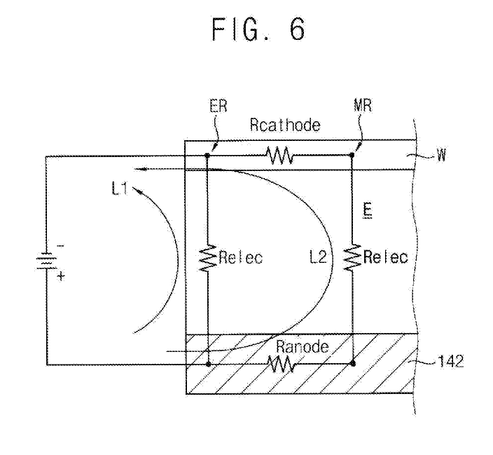

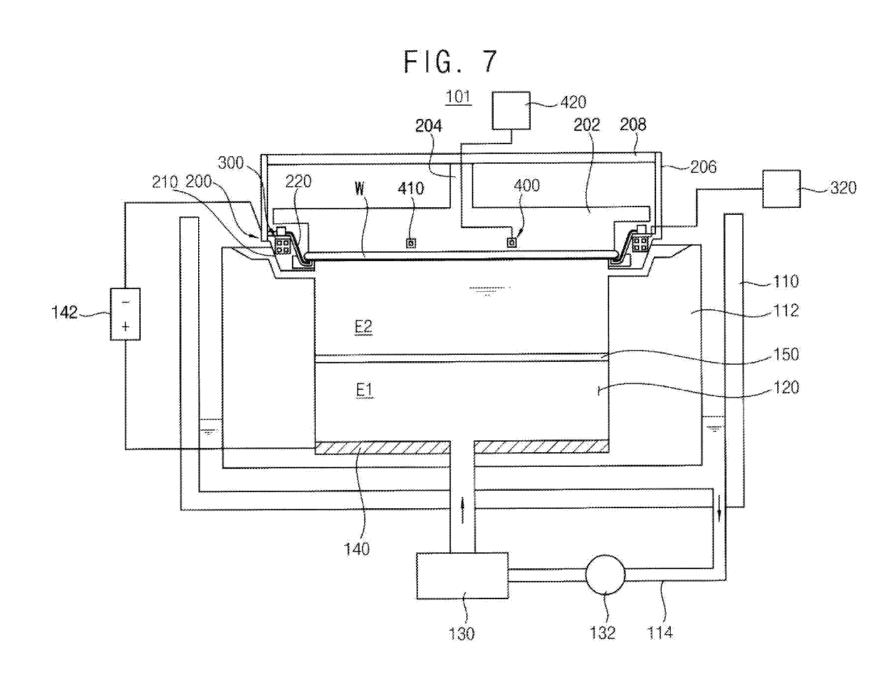

FIG. 1 is a cross-sectional view illustrating an electroplating apparatus in accordance with example embodiments of the inventive concepts. FIG. 2 is a cross-sectional view illustrating a portion of a substrate holder of the electroplating apparatus in FIG. 1. FIG. 3 is a plan view illustrating a magnetic field generating assembly of the electroplating apparatus in FIG. 1. FIG. 4 is a perspective view illustrating portions of electromagnetic coils of the magnetic field generating assembly in FIG. 3. FIGS. 5A and 5B are cross-sectional views illustrating magnetic fields generated by the electromagnetic coils of the magnetic field generating assembly. FIG. 6 is a circuit diagram illustrating a current difference between a center and a periphery of a wafer dipped into a plating solution in an electroplating bath in FIG. 1.

Referring to FIGS. 1 to 6, an electroplating apparatus 100 may comprise an electroplating bath 110 including a plating solution E, a substrate holder 200 above the electroplating bath 110 and configured to hold a substrate, or wafer W, to be submerged into the plating solution E, an anode 140 within the plating solution E in the electroplating bath 110, a cathode 220 connected to the wafer W, and a magnetic field generating assembly 300 having at least one electromagnetic coil 310a, 310b, 312a, 312b extending along a perimeter of the substrate and/or circumference of the wafer W. Additionally, the electroplating apparatus 100 may further include a first power supply 142 electrically connected to the anode 140 and the cathode 220 to supply an electrical signal to the anode 140 and the cathode 220, and a second power supply 320 connected to the electromagnetic coil to supply an electrical signal to the electromagnetic coil.

In example embodiments of the inventive concepts, the electroplating apparatus 100 may use electrolysis of metal ions on a substrate to form a metal layer. The electroplating apparatus 100 may form a plating layer including a metal such as copper (Cu), gold (Au), silver (Ag), platinum (Pt), etc. The substrate may include a substrate such as the silicon wafer W, a quartz substrate, a ceramic substrate, etc.

The electroplating bath 110 may include the plating solution E therein. The electroplating bath 110 may include an electroplating chamber 112 having an inner space 120 in which the plating solution E is included. The plating solution E may be an electrolytic solution, which includes aqueous solution of metallic salts. For example, an aqueous copper sulfate (CuSO₄) solution may be used for electroplating a copper layer on to a surface of the wafer W.

An inlet port may be provided in a lower portion of the electroplating chamber 112 to allow the plating solution to flow into the electroplating chamber 112, and an outlet port may be provided in a top portion of a sidewall of the electroplating chamber 112 to allow the plating solution to flow out of the electroplating chamber 112. An overflow reservoir may be provided between an outer surface of the electroplating chamber 112 and an inner surface of the electroplating bath 110. The plating solution may overflow from the outlet port and be recovered into the overflow reservoir. The overflow reservoir may be in communication with the inner space 120 of the electroplating chamber 112 through a circulation line 114. A pump 132 may be installed in the circulation line 114 to supply the plating solution into the electroplating chamber 112.

The plating solution E, which is supplied into the inner space 120 through the inlet port of the electroplating chamber 112, may flow upwards toward the center of the wafer W and then flow radially outward and across the wafer E. Then, the plating solution E may overflow through the outlet port in the top portion of the sidewall of the electroplating chamber 112 to the overflow reservoir. The plating solution E in the overflow reservoir may be filtered and then may be recirculated by the pump 132.

A heater 130 may be installed in the circulation line 114 to maintain a temperature of the plating solution at a specific level. When the wafer W is loaded into the plating solution E, the heater 130 and the pump 132 may be turned on to circulate the plating solution through the electroplating apparatus.

The anode 140 may be in the lower portion within the electroplating chamber 112. For example, the anode 140 may include copper (Cu). As described later, the substrate holder 200 may include the cathode 220 which contacts and supports the wafer W and is electrically connected to the wafer W. The first power supply 142 may be electrically connected to the anode 140 and the cathode 220, and may bias the wafer to have a negative potential relative to the anode 140. A current including a direct current may flow between the anode 140 and the cathode 220. Thus, the direct current may flow from the anode 140 through a seed layer S on the wafer W to the cathode 220, and an electrochemical reduction reaction may occur on the surface of the wafer W; for example, the seed layer S, which results in the deposition of the copper layer on the seed layer S.

In example embodiments of the inventive concepts, the substrate holder 200 may be on the sidewall of the electroplating chamber 112 and may support the wafer W to be dipped into the plating solution E during electroplating. The substrate holder 200 may be installed fixedly on the sidewall of the electroplating chamber 112. Alternatively or additionally, the substrate holder 200 may be installed movable upwardly and downwardly on the sidewall of the electroplating chamber 112 such that the loaded wafer may be submerged into the plating solution E.

The substrate holder 200 may include an annular support 210 surrounding the wafer W, and a plurality of cathodes 220 on the support 210 to be electrically connected to portions of the periphery of the wafer W respectively. The annular support 210 may have an inner diameter configured to receive the wafer W. A base portion of the support 210 may include an inner protruding base protruding inwardly to the peripheral region of the wafer W received in the support 210, and the inner protruding base may support the peripheral region of the wafer W. A portion of the support 210 other than the base portion may be spaced apart from the periphery of the wafer W by a desired distance.

The cathodes 220 may be installed and supported on the support 210. The cathodes 220 may be arranged in a circumferential direction along an inner surface of the support 210 to be spaced apart from one another. The cathode 220 may extend in a vertical direction along the inner surface of the support 210. The cathode 220 may be an L-shaped or S-shaped electrical finger. An end portion of the cathode 220 may contact the peripheral region of the wafer W, and another end portion of the cathode 220 may be electrically connected to a negative output lead of the first power supply 142.

The substrate holder 200 may further include a lip seal 230 on the inner protruding base of the support 210. A pressing member may press the wafer W toward the electroplating bath 110, and the lip seal 230 may contact the peripheral region of the wafer W, to thereby prevent electrolyte from contacting the cathodes 220.

In example embodiments of the inventive concepts, the magnetic field generating assembly 300 may include at least one electromagnetic coil 310a, 310b, 312a, 312b extending along the circumference of the wafer W over the electroplating bath 110. The electromagnetic coil 310a, 310b, 312a, 312b of the magnetic field generating assembly 300 may be installed in the support 210 of the substrate holder 200. The electromagnetic coil may extend in the circumferential direction along the circumference of the wafer W, and may be configured to generate an electromagnetic force. The electromagnetic force may move the metal ions toward the peripheral region of the wafer W in the electroplating chamber 112 during electroplating, thereby reducing an amount of the deposited metal.

The magnetic field generating assembly 300 may include at least one electromagnetic coil spaced apart from the periphery of the wafer W. For example, the magnetic field generating assembly 300 may include a plurality of electromagnetic coils 310a, 310b, 312a and 312b arranged sequentially from the periphery of the wafer W.

The second power supply 320 may be electrically connected to the electromagnetic coils and may be configured to supply an electrical signal thereto. The second power supply 320 may include a current value controller configured to control a level of current, including a direct current, that is desired to be applied to the electromagnetic coils. The second power supply 320 may include an inversion controller configured to control a direction of current including the direct current flowing in each of, or at least one of, the electromagnetic coils. The second power supply 320 may further include a frequency modulator or a pulse modulator configured to supply current with a desired period to each of, or at least one of, the electromagnetic coils.

As illustrated in FIGS. 2 and 4, the magnetic field generating assembly 300 may include at least two groups of electromagnetic coils 310a, 310b, 312a, 312b. For example, the magnetic field generating assembly 300 may include a first group of electromagnetic coils 310a and 310b and a second group of electromagnetic coils 312a and 312b.

For example, the second power supply 320 may supply a first current to a first electromagnetic coil 310a of the first group of electromagnetic coils such that the first current flows in a first direction. For example, the first direction may correspond to a clockwise direction along the first electromagnetic coil 310a when viewed in a plan view. The second power supply 320 may supply a second current to a second electromagnetic coil 310b of the first group of electromagnetic coils such that the second current flows in a reverse direction of the first direction. For example the first direction may correspond to a counterclockwise direction along the second electromagnetic coil 310b when viewed in a plan view. The second power supply 320 may supply a third current to a first electromagnetic coil 312a of the second group of electromagnetic coils such that the third current flows in the first direction, for example, the clockwise direction along the first electromagnetic coil 312a when viewed in a plan view. The second power supply 320 may supply a fourth current to a second electromagnetic coil 312b of the second group of electromagnetic coils such that the fourth current flows in the reverse direction of the first direction, for example, the counterclockwise direction along the second electromagnetic coil 312b when viewed in a plan view. However, the inventive concepts are not limited thereto. Furthermore, the level of the first current may be the same as or different from the level of the third current. The level of the second current may be the same as or different from the level of the fourth current.

Referring to FIG. 5A, when the first current and the third current flow in the first electromagnetic coil 310a of the first group of electromagnetic coils and the first electromagnetic coil 312a of the second group of electromagnetic coils respectively, a first magnetic field B1 and a third magnetic field B3 may be generated on the peripheral region of the wafer W in the plating solution E. For example, the first current and the third current may have the same current level, when the first electromagnetic coil 310a of the first group of electromagnetic coils is closer to the periphery of the wafer W than the first electromagnetic coil 312a of the second group of electromagnetic coils. Accordingly, the first magnetic field B1 may be greater than the third magnetic field B3 at the same position on the peripheral region of the wafer W.

Referring to FIG. 5B, when the second current and the fourth current flow in the second electromagnetic coil 310b of the first group of electromagnetic coils and the second electromagnetic coil 312b of the second group of electromagnetic coils respectively, a second magnetic field B2 and a fourth magnetic field B4 may be generated on the peripheral region of the wafer W in the plating solution E. For example, the second current and the fourth current have the same current level, when the second electromagnetic coil 310b of the first group of electromagnetic coils is closer to the periphery of the wafer W than the second electromagnetic coil 312b of the second group of electromagnetic coils. Accordingly, the second magnetic field B2 may be greater than the fourth magnetic field B4 at the same position on the peripheral region of the wafer W.

Referring to FIG. 6, when the cathode 220 is electrically connected to the seed layer S on the wafer W, a negative potential is applied to the cathode 220 and a positive potential is applied to the anode 140, current may flow from the anode 140 to the wafer W in the plating solution E within the electroplating chamber 112. Here, closed circuits L1 and L2 may be formed to pass through nodes ER and MR on the peripheral region and the middle region of the wafer W respectively. A current difference Alec between currents flowing through the closed circuits L1 and L2 may be calculated by following Equation (1).

$$Δ Iec = Iedge - Icenter = \frac{VRcathode}{Relec ( Relec + Rcathode )} \qquad Equation ( 1 )$$

Here, ledge is current flowing through the edge closed circuit L1, Icenter is current flowing through the closed circuit L2, and Rcathode is resistance between the edge region ER and the middle region MR of the seed layer S.

Since the current difference between the closed circuits L1 and the L2 is proportional to Rcathode, voltage drop (IR drop) may occur when the current passes through the seed layer S having a relatively small thickness, and thus, a current concentration may be generated in the edge region of the wafer W. Accordingly, metal ions in the plating solution E may be attracted more to the edge region of the wafer W than to the middle region, resulting in a deposition of a relatively thicker metal layer on the edge region of the wafer W.

In example embodiments of the inventive concepts, the magnetic field generating assembly 300 may be installed in the support 210 of the substrate holder 200 and the electromagnetic coil of the magnetic field generating assembly 300 may extend in the circumferential direction along the circumference of the wafer W. As current flows in the electromagnetic coil, a magnetic field may be generated to act on metal ions to be deposited on the peripheral region of the wafer W. Thus, a magnetic force generated by the electromagnetic coil of the magnetic field generating assembly 300 may be exerted on the metal ions moving toward the peripheral region of the wafer W in the plating solution E.

The net force of the electric field and the magnetic force may act on the metal ions, and thus, some of the metal ions may not move to the peripheral region of the wafer W and may move in an outer radial direction from the periphery of the wafer W and then overflow through the outlet port in the top portion of the sidewall of the electroplating chamber 112. Accordingly, the number of the metal ions moving to the edge of the wafer W may be reduced, to thereby decrease a thickness of the metal layer deposited on the peripheral region of the wafer W.

For example, the second power supply 320 may adjust a level and a direction of currents flowing through the first electromagnetic coil 310a of the first group of electromagnetic coils and the first electromagnetic coil 312a of the second group of electromagnetic coils of the magnetic field generating assembly 300 such that some of the copper ions may move outwardly from the peripheral region of the wafer W in the outer radial direction.

Additionally, the second power supply 320 may adjust the level and the direction of current flowing through the first electromagnetic coil 310a of the first group of electromagnetic coils and the first electromagnetic coil 312a of the second group of electromagnetic coils of the magnetic field generating assembly 300 such that the number of the copper ions moving to the middle region of the wafer W may be maintained or increased, not be decreased.

As mentioned above, the magnetic generating assembly 30 may include at least one electromagnetic coil extending in the circumferential direction along the circumference of the wafer W. As the current flows through the electromagnetic coil, a magnetic field may be generated on the peripheral region of the wafer W. Thus, a magnetic field may act on the metal ions moving toward the peripheral region of the wafer W such that some of the metal ions may move outwardly from the peripheral region of the wafer W in the outer radial direction.

Accordingly, the number of the metal ions deposited on the peripheral region of the wafer W may be reduced, thereby decreasing a thickness of the metal layer plated on the peripheral region of the wafer W. Therefore, a distribution density of the current flowing from the anode 140 through the wafer W may be uniform, or more uniform, over the entire surface of the wafer W, thereby depositing a metal layer having a uniform, or more uniform, thickness.

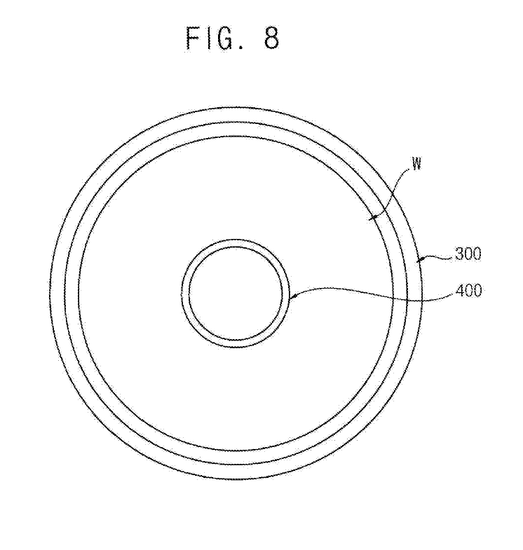

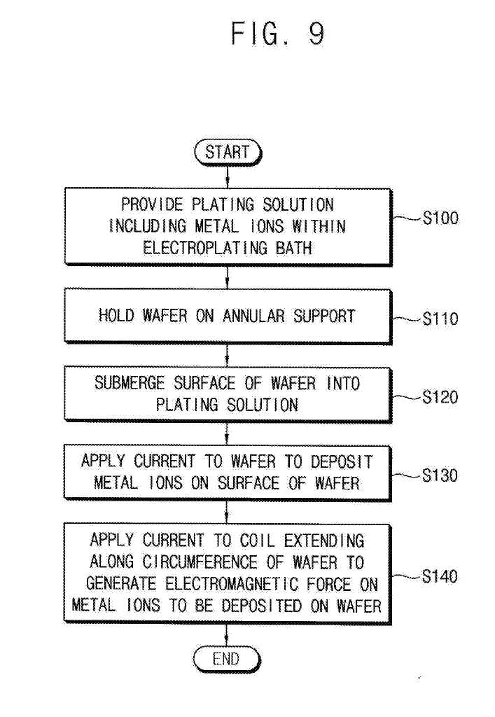

FIG. 7 is a cross-sectional view illustrating an electroplating apparatus in accordance with example embodiments of the inventive concepts. FIG. 8 is a plan view illustrating first and second magnetic field generating assemblies of the electroplating apparatus in FIG. 7. The electroplating apparatus may be substantially the same as or similar to the electroplating apparatus as described with reference to FIGS. 1 to 4, except for an addition of a second magnetic field generating assembly and additional elements. Thus, same reference numerals will be used to refer to the same or like elements and any further repetitive explanation concerning the above elements will be omitted.

Referring to FIGS. 7 and 8, an electroplating apparatus 101 may further include a pressurizing member 202 configured to pressurize a wafer W on a support 210, a membrane 150 within an electroplating chamber 112 and a second magnetic field generating assembly 400.

In example embodiments of the inventive concepts, a substrate holder 200 may further include the pressurizing member 202 which is configured to pressurize and clamp the wafer W on the support 210. In particular, the support 210 and the pressurizing member 202 of the substrate holder 200 may be connected to be supported to the top plate 208 by connection members 206. The pressurizing member 202 may be installed movable upward and downward on the support 210.

In order to load the wafer W into the support 210, the pressurizing member 202 may be raised by a spindle 204 until the pressurizing member 202 touches the top plate 208. The wafer W may be inserted between a lower surface of the pressurizing member 202 and the support 210, and then, may be seated on an inner protruding base of the support 210. As illustrated in FIG. 7, the pressurizing member 202 may be lowered to pressurize the wafer W against a lip seal on the inner base protruding base of the support 210, and thus, cathodes 220 may contact the peripheral region of the wafer W.

The pressurizing member 202 may transmit a vertical force and a torque through the spindle 204. The vertical force may cause the wafer W to compress the lip seal to form a fluid tight seal. Additionally, the substrate holder 200 may be rotated by the torque.

In example embodiments of the inventive concepts, the membrane 150 may be within the electroplating chamber 112 to divide an inner space 120 into two separate spaces. The membrane 150 may be an ion selective membrane. The electroplating chamber 112 may be divided into an anode region E1 and a cathode region E2.

The membrane 150 may prevent particles generated at the anode 140 from entering the cathode region E2 and contaminating the cathode region E2. The membrane 150 may allow ionic communication between the anode region E1 and the cathode region E2.

In example embodiments of the inventive concepts, the electroplating apparatus 101 may include a first magnetic field generating assembly 300 having at least one electromagnetic coil surrounding a circumference of the wafer W and the second magnetic field generating assembly 400 having at least one electromagnetic coil 410 on the middle region of the wafer W. The electroplating apparatus 101 may include a second power supply 320 connected to the electromagnetic coil of the first magnetic field generating assembly 400 to supply an electrical signal thereto and a third power supply 420 connected to the electromagnetic coil of the second magnetic field generating assembly 400 to supply an electrical signal thereto.

The second magnetic field assembly 400 may be installed in the pressurizing member 202 of the substrate holder 200 corresponding to the middle region of the wafer W. The electromagnetic coil 410 of the second magnetic field generating assembly 400 may extend in a circumferential direction on the middle region of the wafer W, and may generate an electromagnetic force on metal ions moving toward the wafer W in the electroplating chamber 112 during electroplating, thereby increasing an amount of the metal deposited on the middle region of the wafer W.

The third power supply 420 may be electrically connected to the electromagnetic coil 410 of the second magnetic field generating assembly 400 and supply an electrical signal thereto. The third power supply 420 may include a current value controller configured to control a level of current applied to the electromagnetic coil. The third power supply 420 may include an inversion controller configured to control a direction of current flowing in the electromagnetic coil. The third power supply 420 may further include a frequency modulator and/or a pulse modulator configured to supply current with a desired period to the electromagnetic coil.

For example, the third power supply 420 may supply current to the electromagnetic coil 410 of the second magnetic field generating assembly 400 such that the current flows in a clockwise direction or a counterclockwise direction. The level of the current, on-off period of the current supply, and/or other aspects. may be determined in consideration of the amount of the metal to be deposited on the middle region of the wafer W.

Hereinafter, a method of plating a metal layer using the electroplating apparatus in FIG. 1 or FIG. 7 will be explained.

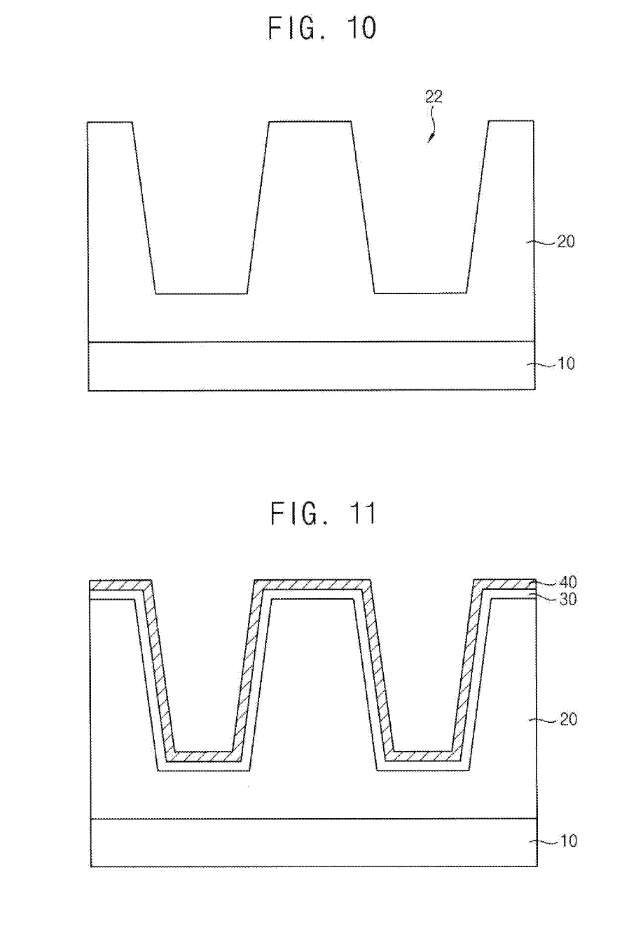

FIG. 9 is a flow chart illustrating an electroplating method in accordance with example embodiments of the inventive concepts.

Referring to FIGS. 1, 7 and 9, a plating solution E including metal ions may be provided within an electroplating bath 110 (S100).

In example embodiments of the inventive concepts, the plating solution E may be supplied into an inner space 120 of an electroplating chamber 112 of the electroplating bath 110. For example, the plating solution may include an aqueous copper sulfate (CuSO₄) solution.

A wafer W may be held by a substrate holder 200 (S110), and then, a surface of the wafer W may be submerged into the plating solution E (S120).

In example embodiments of the inventive concepts, a pressurizing member 202 may be raised up by a spindle 204 until the pressurizing member 202 touches a top plate 208, the wafer W may be inserted between a lower surface of the pressurizing member 202 and an annular support 210, and then, may be seated on an inner protruding base of the support 210. The pressurizing member 202 may be lowered to pressurize the wafer W against a lip seal on the inner base protruding base of the support 210, and thus, cathodes 220 may contact a peripheral region of the wafer W. Then, the substrate holder 200 may be lowered to submerge the wafer W into the plating solution E.

Current may be applied to the wafer W to deposit a metal layer on the surface of the wafer W (S130).

A positive potential may be applied to an anode 140 within the electroplating chamber 112 and facing with the wafer W and a negative potential may be applied to a cathode 220 electrically connected to a seed layer S on the surface of the wafer W. Thus, current may flow from the anode 140 to the wafer W in the plating solution E within the electroplating chamber 112. Accordingly, positive metal ions (for example, copper ions) may be attracted to the seed layer S on the wafer W and may receive electrons from the cathode 220 to form the metal layer on the wafer W.

Current may be applied to an electromagnetic coil extending along a circumference of the wafer W to generate an electromagnetic force on the metal ions to be deposited on the wafer W (S140).

Current may be supplied to the electromagnetic coil extending in a circumferential direction along the circumference of the wafer W. As the current flows in the electromagnetic coil, a magnetic field may be generated. The magnetic field may act on the metal ions to be deposited on the peripheral region of the wafer W. Thus, a magnetic force may be exerted on the metal ions moving toward the peripheral region of the wafer W to move some of the metal ions outwardly from the peripheral region of the wafer W in an outer radial direction.

Accordingly, the number of the metal ions deposited on the peripheral region of the wafer W may be reduced, to thereby decrease a thickness of the metal layer deposited on the peripheral region of the wafer W. Therefore, a distribution density of the current flowing from the anode 140 through the wafer W may be uniform, or more uniform, over the entire surface of the wafer W, thereby depositing a metal layer having a uniform, or more uniform, thickness.

In example embodiments of the inventive concepts, a level, a direction, a polarity, and/or other aspects of the current flowing through the electromagnetic coil may be controlled. Additionally, a plurality of electromagnetic coils may be to surround the wafer W, and the level, the direction, etc. of the current flowing through the electromagnetic coil may be controlled.

Currents having different levels and directions may be applied to the electromagnetic coils, to form magnetic fields having different magnitudes and directions on the peripheral region and the middle region of the wafer W. Due to the net force of the magnetic force and the electric field, metal ions moving toward the wafer W may have a uniform, or more uniform, distribution across the entire surface of the wafer W.

Hereinafter, a method of manufacturing a semiconductor device using the electroplating method in FIG. 9 will be explained.

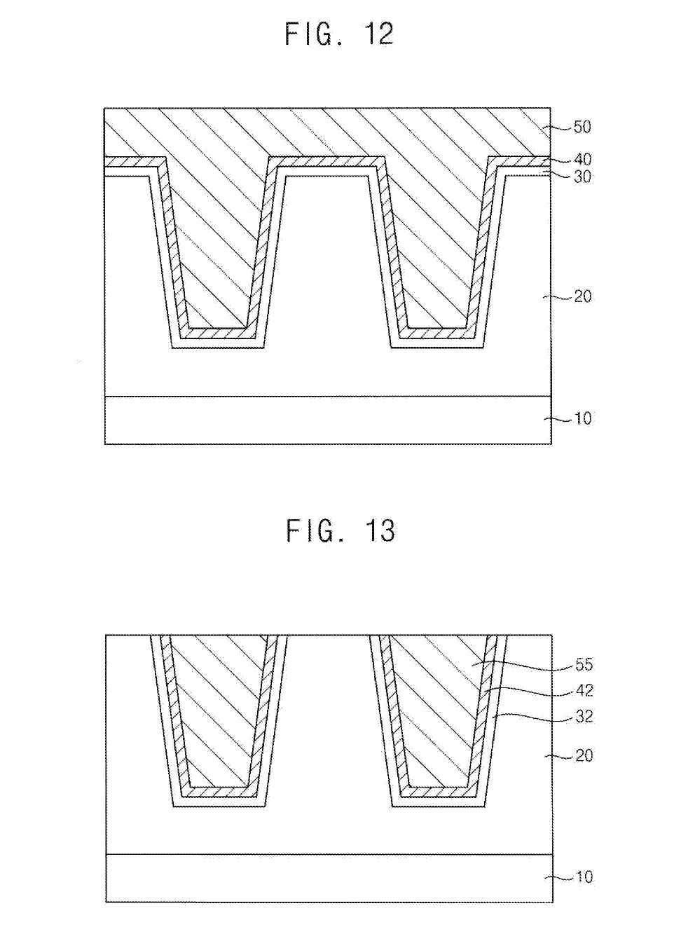

FIGS. 10 to 13 are views illustrating a method of manufacturing a semiconductor device package in accordance with example embodiments of the inventive concepts.

Referring to FIG. 10, a first insulating interlayer 20 may be formed on a substrate 10, and trenches 22 may be formed in the first insulating interlayer 20.

The substrate 10 may include a semiconductor material, e.g., silicon, germanium, silicon-germanium, etc., or III-V semiconductor compounds, e.g., GaP, GaAs, GaSb, etc. In an example embodiment, the substrate 10 may include an SOI substrate or a GOI substrate.

Although not illustrated in the figures, various elements, for example, a word line, a transistor, a diode, a source/drain layer, a source line, a wiring, and/or other elements may be formed on the substrate 10.

The first insulating interlayer 20 may be formed of a low-k dielectric material, e.g., silicon oxide doped with carbon (SiCOH) or silicon oxide doped with fluorine (F—SiO₂), a porous silicon oxide, spin on organic polymer, or an inorganic polymer, e.g., hydrogen silsesquioxane (HSSQ), methyl silsesquioxane (MSSQ), etc. However, the inventive concepts are not limited thereto.

The trenches 22 may be formed by a photolithography process using a photoresist pattern (not shown). FIG. 10 shows that two trenches are formed, however, the inventive concepts may not be limited thereto, and a plurality of trenches may be formed. Hereinafter, only the case in which the two trenches are formed will be illustrated.

Referring to FIGS. 11 and 12, a barrier layer 30 and a seed layer 40 may be formed sequentially on inner walls of the trenches 22 and a top surface of the first insulating interlayer 20, and a metal layer 50 may be formed on the barrier layer 30 to sufficiently fill remaining portions of the trenches 22.

The barrier layer 30 may include a metal nitride, e.g., tantalum nitride, titanium nitride, etc., and/or a metal, e.g., tantalum, titanium, etc. The metal layer 50 may include a metal, e.g., copper.

In example embodiments of the inventive concepts, the barrier layer 30 may be formed by a chemical vapor deposition (CVD) process, an atomic layer deposition (ALD) process, a physical vapor deposition (PVD) process, and/or other deposition methods. Thus, the barrier layer 30 may be conformally formed on the inner walls of the trenches 22 and the top surface of the first insulating interlayer 30.

Then, the seed layer 40 may be formed on the barrier layer 30. The seed layer may be formed by CVD processes, PVD process, ALD processes, and/or other deposition methods. Then, an electroplating process may be performed to form the metal layer 50 on the seed layer 40.

Hereinafter, a method of electroplating the metal layer 50 will be explained with reference to FIGS. 1, 7 and 9.

Referring again to FIGS. 1, 7 and 9, first, a plating solution E may be supplied into an electroplating chamber 112 of an electroplating bath 110 of an electroplating apparatus 100, 101, the substrate 10 may be held by a substrate holder 200, and then, a surface of the substrate 10 may be submerged into the plating solution E.

As the substrate 10 is seated on an inner protruding base of an annular support 210, cathodes 220 may contact a peripheral region of the substrate 10. Then, a substrate holder 200 may be lowered to submerge the substrate 10 into the plating solution E.

Then, current may be applied to the substrate 10 to deposit a metal layer on the surface of the substrate 10. A positive potential may be applied to an anode 140 within the electroplating chamber 112 of the electroplating bath 110 and facing with the substrate 10 and a negative potential may be applied to a cathode 220 electrically connected to the seed layer 40 on the substrate 10. Thus, current may flow from the anode 140 to the substrate 10 in the plating solution E within the electroplating chamber 112 of the electroplating bath 110. For example, positive metal ions (for example, copper ions) may be attracted to the seed layer 40 on the substrate 10 and may receive electrons from the cathode 220 to form the metal layer 50 on the substrate 10.

Then, current may be applied to an electromagnetic coil extending along a circumference of the substrate 10 to generate an electromagnetic force on the metal ions to be deposited on the substrate 10. Current may be supplied to the electromagnetic coil extending in a circumferential direction along the circumference of the substrate 10. As the current flows in the electromagnetic coil, a magnetic field may be generated. The magnetic field may act on the metal ions to be deposited on the peripheral region of the substrate 10. Thus, a magnetic force may be exerted on the metal ions moving toward the peripheral region of the substrate 10 to move some of the metal ions outwardly from the peripheral region of the substrate 10 in an outer radial direction.

Accordingly, the number of the metal ions deposited on the peripheral region of the substrate 10 may be reduced, to thereby decrease a thickness of the metal layer deposited on the peripheral region of the substrate 10. Thus, the metal layer 50 having a uniform, or more uniform, thickness across the entire surface of the substrate 10 may be formed.

In example embodiments of the inventive concepts, a current level, a direction, a polarity, and/or other aspects of the current flowing through the electromagnetic coil may be controlled. Additionally, a plurality of electromagnetic coils may be surrounding the substrate 10, and the level, the direction, etc. of the current flowing through the electromagnetic coil may be controlled.

Currents having different current levels and/or directions may be applied to the electromagnetic coils, to form magnetic fields having different magnitudes and/or directions on the peripheral region and the middle region of the substrate 10. Due to the net force of the magnetic force and the electric field, metal ions moving toward the substrate 10 may have a uniform, or more uniform, distribution across the entire surface of the substrate 10.

Before the metal layer 50 is formed, a liner (not shown) may be further formed on the barrier layer 30. The liner may include of a metal, e.g., cobalt, ruthenium, etc.

Referring to FIG. 13, the metal layer 50 and the barrier layer 30 may be planarized until the top surface of the first insulating interlayer 20 may be exposed to form a metal pattern 55 in the trench 22.

In example embodiments of the inventive concepts, the planarization process may be performed by a chemical mechanical polishing (CMP) process and/or an etch back process. The metal layer 50 may have a uniform, or more uniform, thickness profile across the entire substrate 10. Accordingly, occurrences of copper residue and dishing due to overly CMP may be mitigated.

Thus, a wiring structure including the metal pattern 55 may be formed on the substrate 10.

The above semiconductor device may be applied to various memory devices and system. For example, the semiconductor device may be applied to a wiring structure included in logic devices such as central processing units (CPUs), main processing units (MPUs), or application processors (APs), or the like, and volatile memory devices such as DRAM devices, SRAM devices, or HBM devices, or non-volatile memory devices such as flash memory devices, PRAM devices, MRAM devices, ReRAM devices, and/or the like.

The foregoing is illustrative of example embodiments of the inventive concepts and is not to be construed as limiting thereof. Although a few example embodiments of the inventive concepts have been described, those skilled in the art will readily appreciate that many modifications are possible in example embodiments of the inventive concepts without materially departing from the novel teachings and advantages of the present invention. Accordingly, all such modifications are intended to be included within the scope of example embodiments of the inventive concepts as defined in the claims.

1. An electroplating apparatus, comprising:
an electroplating bath including an anode and a plating solution;
a substrate holder configured to hold a substrate to be submerged into the plating solution, the substrate holder including a support and a cathode on the support, the cathode configured to electrically connect to a periphery of the substrate;
a magnetic field generating assembly in the support, the magnetic field generating assembly including at least one electromagnetic coil extending along a perimeter of the substrate; and
a power supply configured to supply current to the at least one electromagnetic coil.

2. The electroplating apparatus of claim 1, wherein the at least one electromagnetic coil is inside the support.

3. The electroplating apparatus of claim 1, wherein the magnetic field generating assembly includes a plurality of the electromagnetic coils arranged sequentially from the periphery of the substrate.

4. The electroplating apparatus of claim 3, wherein the power supply is configured to supply a first current to a first electromagnetic coil spaced apart from the periphery of the substrate by a first distance, and the power supply is configured to supply a second current to a second electromagnetic coil, the second magnetic coil spaced apart from the periphery of the substrate by a second distance greater than the first distance.

5. The electroplating apparatus of claim 4, wherein the power supply is configured to supply a current level of the first current greater than a current level of the second current.

6. The electroplating apparatus of claim 4, wherein the power supply is configured to supply the first current in a first direction, and the power supply is configured to the second current in a second direction, and the first direction is equal to the second direction.

7. The electroplating apparatus of claim 4, wherein the power supply is configured to supply the first current in a first direction, and the power supply is configured to supply the second current in a second direction, and the first direction is opposite to the second direction.

8. The electroplating apparatus of claim 1, wherein the power supply is configured to control the current flowing through the at least one electromagnetic coil to form an electromagnetic field such that metal ions moving toward a peripheral region of the substrate deviate from the peripheral region of the substrate to move outwardly from a center of the substrate.

9. The electroplating apparatus of claim 1, wherein the power supply is configured to control the current flowing through the at least one electromagnetic coil to form an electromagnetic field such that metal ions moving toward a peripheral region of the substrate deviate from the peripheral region of the substrate and move to a middle region of the substrate.

10. The electroplating apparatus of claim 1, wherein the magnetic field generating assembly includes first and second groups of electromagnetic coils.

11. The electroplating apparatus of claim 10, wherein the power supply is configured to control current flowing through the first group of electromagnetic coil to form a first magnetic field on a peripheral region of the substrate, and the power supply is configured to control current flowing through the second group of electromagnetic coil to form a second magnetic field on the peripheral region of the substrate, a direction of a force from the second magnetic field being opposite to a direction of a force from the first magnetic field.

12. The electroplating apparatus of claim 10, wherein the power supply is configured to control current flowing through the first group of electromagnetic coil to form an electromagnetic field such that metal ions moving toward a peripheral region of the substrate deviate from the peripheral region of the substrate to move outwardly from a center of the substrate.

13. The electroplating apparatus of claim 1, further comprising
a second magnetic field generating assembly including at least one electromagnetic coil extending along a middle region of the substrate; and
a second power supply connected to the at least one electromagnetic coil of the second magnetic field generating assembly and configured to supply current to the at least one electromagnetic coil of the second magnetic field generating assembly.

14. (canceled)

15. (canceled)

16. (canceled)

17. (canceled)

18. An electroplating apparatus, comprising:
an electroplating bath including a plating solution received therein;
a substrate holder configured to hold a substrate to be submerged into the plating solution;
an anode within the electroplating bath;
a cathode configured to electrically contact a periphery of the substrate;
a magnetic field generating assembly on the electroplating bath and including at least one electromagnetic coil extending along a perimeter of the substrate; and
a power supply configured to supply current to the at least one electromagnetic coil.

19.-40. (canceled)

41. An electroplating apparatus, comprising:
a first electromagnetic coil configured to extend along a perimeter of a substrate;
a first power supply configured to provide a first current through the substrate to electrochemically deposit metal ions to form a metal layer on the substrate; and
a second power supply configured to supply a second current to the first electromagnetic coil to form an electromagnetic force acting on the metal ions to move outwardly from a periphery of the substrate.

42. The electroplating apparatus of claim 41, wherein
the first power supply includes a first DC power supply, and
the second power supply includes a second DC power supply.

43. The electroplating apparatus of claim 41, wherein the first electromagnetic coil extends along a circumference of the substrate.

44. The electroplating apparatus of claim 41, further comprising:
a second electromagnetic coil configured to extend along middle region of the substrate; and
a third power supply configured to supply a third current to the second electromagnetic coil.

45. The electroplating apparatus of claim 44, wherein the third power supply includes a third DC power source.
